(19) United States
(12) Patent Application Publication
(10) Pub. No.: US 2008/0105936 A1
(43) Pub. Date: May 8, 2008

(54) SURFACE PRESSURE DISTRIBUTION SENSOR

(75) Inventor: Masahito NAKAMURA, Miyagi-ken (JP)

Correspondence Address: BEYER WEAVER LLP, P.O. BOX 70250, OAKLAND, CA, 94612-0250, US

(73) Assignee: ALPS ELECTRIC CO., LTD., Tokyo (JP)

(21) Appl. No.: 11/964,645

(22) Filed: Dec. 26, 2007

Related U.S. Application Data
(63) Continuation of application No. PCT/JP2006/312100, filed on Jun. 16, 2006.

(30) Foreign Application Priority Data
Jun. 28, 2005 (JP) 2005-188189

(51) Int. Cl. H01L 29/84

(52) U.S. Cl. 257/415

(57) ABSTRACT

[Object] An object of the present invention is to provide a surface pressure distribution sensor capable of maintaining high reliability of lines in a configuration having a folded portion, precisely and stably detecting a surface pressure distribution, and being manufactured with a simple configuration and at low cost.

[Solving Means] In the present invention, a first lead line group is placed adjacent to a first line group on a first substrate, a second lead line group connected to a second line group is placed on a second substrate, the second lead line group extends over a boundary portion and connects to the first lead line group on the first substrate, the width of conductors of the first lead line group is smaller than the width of conductors of the first line group and the width of conductors of the second line group, and the width of conductors of the second lead line group positioned in a folded portion of the boundary portion is larger than the width of the conductors of the first lead lined group.

### CROSS REFERENCE TO RELATED APPLICATION

This is a continuation of International Application No. PCT/JP2006/312100 filed Jun. 16, 2006, which is incorporated herein by reference in its entirety.

### TECHNICAL FIELD

The present invention relates to a surface pressure distribution sensor to measure fine concavities and convexities of an object.

### BACKGROUND ART

A surface pressure distribution sensor to detect fine concavities and convexities on a surface of an object pressed onto a detecting surface as distribution of pressing forces has been widely known as a sensor to transform a shape of a rough surface into data (e.g., see Patent Document 1).

In this known type of surface pressure distribution sensor, as illustrated in FIG. 8, semiconductor switching elements 101 are placed in a matrix pattern on a substrate, and electrodes 102 connect to one of terminals of the respective semiconductor switching elements 101. On the opposed plane of the semiconductor substrate, a flexible film having a conductive film is placed to face the electrodes 102, with a predetermined spacing from the electrodes 102. A certain voltage is applied to this conductive film. If an object having fine concavities and convexities on its surface is pressed onto the flexible film, the flexible film yields to the pressure and is deformed in accordance with the concavities and convexities of the object. In this way, the deformed portion of the conductive film comes into contact with the electrodes of the semiconductor substrate, so that the semiconductor switching elements 101 in the corresponding portion are sequentially started to read a surface pressure.

The above-described conventional surface pressure distribution sensor includes a semiconductor substrate. Such a semiconductor substrate is typically expensive. Particularly, when the surface pressure distribution sensor is used as a fingerprint detecting sensor, a sufficiently large surface area to press a finger is required. The use of semiconductor substrates having such a large surface area makes it difficult to manufacture surface pressure distribution sensors at low cost. Furthermore, a stable contact between exposed portions of the semiconductor switching elements and the conductive film needs to be maintained over long periods in order to detect fine concavities and convexities on a surface even if the pressing force is small. However, in the conventional surface pressure distribution sensor, it is difficult to maintain cleanness of the contact portion between exposed portions of the semiconductor switching elements and the conductive film over long periods.

In view of this background, the applicant of the present application has developed a surface pressure distribution sensor and has filed a patent application about the surface pressure distribution sensor (see Patent Document 2). In the surface pressure distribution sensor, the entire configuration includes row lines extending in a first direction placed on a first substrate and column lines extending in a second direction placed on a second substrate. The first substrate is made of a flexible film substrate and is superimposed on the second substrate such that the row lines and the column lines face each other. Distribution of surface pressures can be measured based on change in capacitance at intersections between the row lines and column lines.

Patent Document 1: Japanese Examined Patent Application Publication No. 7-58234

Patent Document 2: Japanese Unexamined Patent Application Publication No. 2004-317403

### DISCLOSURE OF INVENTION

### Problems to be Solved by the Invention

In the surface pressure distribution sensor described in Patent Document 2, a plurality of row lines 111 are placed in parallel in the vertical direction on a substrate 110 illustrated in FIG. 9, and a plurality of column lines 113 are placed in parallel in the horizontal direction on a substrate 112. A plurality of lead lines 115 are placed along one of edges of the substrate 112 and extend to one of edges of the substrate 110 so as to serve as lead lines 116. The lead lines 116 and lead lines 117 extending from the row lines 111 concentrate to and connect to a driving element 118.

At least one of the plurality of row lines 111 and the plurality of column lines 113 is covered by an insulating layer, and the substrate 112 is folded to the substrate 110 along a fold line 114 illustrated in FIG. 9 in the manner illustrated in FIG. 10, so that the plurality of row lines 111 and the plurality of column lines 113 face each other at substantially right angles. Accordingly, a surface pressure distribution sensor D is constituted. In the surface pressure sensor D having the above-described configuration, a rectangular area where the plurality of row lines 111 and the plurality of column lines 113 face each other at substantially right angles in a plan view serves as a sensing area 120.

The surface pressure distribution sensor D having the above-described configuration does not include a semiconductor substrate and is advantageous in its low manufacturing cost. However, since the configuration of folding the substrate 112 to the substrate 110 is adopted, part of the lines needs to be folded, which disadvantageously imposes stress on the folded part of the lines. For example, even if a folding operation during manufacturing does not directly cause break of the lines, stress constantly acts on the folded lines 115. Therefore, the lines in the surface pressure distribution sensor D may be partially broken during long use.

In order to overcome such a problem of stress imposed on the lines, thick lines can be used at the folded portion of the substrates so that the lines are not broken even if some stress is imposed on the lines. However, a reduction in size and weight is demanded in this type of surface pressure sensor, and thus the size of substrates and the width and space of lines constituting the surface pressure sensor should desirably be as small as possible. Accordingly, the size of substrate around the sensing area 120 should desirably be as small as possible.

In order to precisely measure a surface pressure in a small area in accordance with the application of a fingerprint sensor or the like, the row lines 111 and the column lines 113 need to be fine. Also, in order to minimize the area of substrates, the lead lines 115 and 116 need to be fine. If fine lines are used, a problem in durability of the lines is likely to occur due to stress of folding, which reduces reliability of the lines disadvantageously.

The present invention has been made in view of the above-described circumstances, and an object of the present invention is to provide a surface pressure distribution sensor capable of maintaining high reliability of lines even in a configuration having a folded portion of substrates, precisely and stably detecting a surface pressure distribution over long periods, and being manufactured with a simple configuration and at low cost.

### Means for Solving the Problems

The present invention has been made in view of the above-described circumstances. According to the present invention, there is provided a surface pressure distribution sensor that includes a first substrate provided with a first line group having a plurality of conductors arranged in parallel; a second substrate provided with a second line group having a plurality of conductors arranged in parallel; and a boundary portion connecting the first substrate to the second substrate, the first substrate and the second substrate connecting to each other such that folding at the boundary portion allows the first line group of the first substrate and the second line group of the second substrate to face each other and cross each other, and that is capable of detecting distribution of surface pressures based on change in capacitance at intersections of the conductors of the first line group and the conductors of the second line group. A first lead line group independent of the first line group is placed adjacent to the first line group on the first substrate. A second lead line group connected to the second line group is placed on the second substrate. The second lead line group extends over the boundary portion and connects to the first lead line group on the first substrate. The width of conductors of the first lead line group is smaller than the width of the conductors of the first line group and the width of the conductors of the second line group. The width of conductors of the second lead line group positioned in a folded portion of the boundary portion is larger than the width of the conductors of the first lead lined group.

Since the width of the conductors of the second lead line group placed in the boundary portion as a folded portion is larger than the width of the conductors of the first lead line group, the durability of the conductors of the second lead line group positioned in the folded portion is high, and thus a wiring structure resistant to folding stress can be provided. Also, since the conductors of the first lead line group is thinner than the conductors of the second lead line group, the conductors of the first lead line group can be placed at high density in a narrow area next to the first line group placed on the first substrate. The conductors of the first lead line group, which are fine lines, are not folded, and thus stress is not imposed thereon.

The present invention has been made in view of the above-described circumstances. The first lead line group is placed in parallel to the first line group on the first substrate. The width of each conductor of the first lead line group is smaller than the width of each conductor of the first line group. The entire width of the first lead lined group is smaller than the entire width of the first line group. The second substrate is connected on a lateral side of the first line group via the boundary portion. The second line group and the second lead line group are arranged in a direction orthogonal to each conductor of the first lead line group.

Since the entire width of the second lead lined group can be smaller than the entire width of the first line group, the first lead line group can be placed even in a narrow area next to the first line group on the substrate. As a result, a wasted portion on the substrate can be minimized to achieve miniaturization of the substrate, which realizes a reduction in size and weight of the entire surface pressure distribution sensor.

The present invention has been made in view of the above-described circumstances. One side of the first line group is collectively wired in a part on the first substrate so that a first element connecting area is formed. One side of the first lead line group is collectively wired in another part on the first substrate so that a second element connecting area is formed. The first element connecting area is adjacent to the second element connecting area. A common sensing driving element or individual sensing driving elements connect to those element connecting areas.

The driving element can be easily placed in the collectively wired area on the substrate.

The present invention has been made in view of the above-described circumstances. Each conductor of the second line group on the second substrate extends over the boundary portion onto the first substrate with a constant width. The conductors of the first lead line group are longer near the first line group and shorter on the opposite side of the first line group so that heads of the conductors of the first lead line group are positioned stepwise in a length direction of the first lead line group. The conductors of the second lead line group extending over the boundary portion connect to the stepwise-positioned heads of the conductors of the first lead line group.

Advantages

According to the present invention, since the width of each conductor of the second lead line group is large in a folded portion of the substrates, an effect of stress imposed on each conductor of the second lead line group in the folded portion can be reduced. Accordingly, a configuration of a surface pressure distribution sensor with a highly reliable lines having lower possibility of break even by use over time can be provided.

### BEST MODE FOR CARRYING OUT THE INVENTION

Hereinafter, an embodiment of the present invention is described with reference to the drawings, but the present invention is not limited to the embodiment described below. In the drawings, each element is illustrated at different scale for easy illustration.

FIG. 1 is an illustration of an equivalent circuit of a surface pressure distribution sensor according to this embodiment, FIG. 2 is a developed view of a specific configuration of the surface pressure distribution sensor before assembly, FIG. 3 illustrates a plan configuration of the surface pressure distribution sensor after assembly, FIG. 4 is a cross-sectional view taken along the line A-A′ of the surface pressure distribution sensor illustrated in FIG. 3, and FIG. 5 is a cross-sectional view taken along the line B-B′ of the surface pressure distribution sensor illustrated in FIG. 3.

The surface pressure distribution sensor 1 according to this embodiment has a developed configuration in which a first substrate 3 provided with a first line group (row line group) 2 and a second substrate 6 provided with a second line group (column line group) 5 are connected to each other while being adjacent to each other via a boundary portion 7 serving as a folded portion, as illustrated in FIG. 2. By assembling the first substrate 3 and the second substrate 6 by folding them along the boundary portion 7 so that the first and second substrates 3 and 6 face each other in the manner illustrated in FIG. 3, an integral configuration illustrated in FIGS. 3 to 5 can be made.

In the substrates 3 and 6, the second substrate 6 superimposed on the first substrate 3 may have flexibility to yield to pressure in accordance with concavities and convexities when a concave and convex surface having a size of about several μm to several tens of μm is pressed onto its surface. For example, a flexible film, such as a polyester film having a thickness of about 1 to 30 μm, is preferably used.

Each of the first substrate 3, the second substrate 6, and the boundary portion 7 is constituted by a flexible substrate including a flexible film in this embodiment. As illustrated in FIG. 2, each of the first substrate 3 and the second substrate 6 is rectangular, and the second substrate 6 extends on the side of one of edges of the first substrate 3 via the boundary portion 7. The horizontal widths of the first substrate 3 and the second substrate 6 are almost equal to each other. The upper edge of the first substrate 3 and the upper edge of the second substrate 6 are collinear, and the vertical length of the first substrate 3 is a little longer than the vertical length of the second substrate 6. Thus, by superimposing the second substrate 6 on the first substrate 3 by folding them along the boundary portion 7, the upper edges and side edges of the first and second substrates 3 and 6 can be collinear, as illustrated in FIG. 3. In this state, part of the first substrate 3 is exposed from the second substrate 6, and the exposed portion, which is part of the first substrate 3, serves as an element connecting area portion 3A.

The first line group 2 placed on the first substrate 3 is a set of a plurality of strip conductors 2A extending in the vertical direction and arranged in the horizontal direction on the first substrate 3, as illustrated in FIG. 2. The conductors 2A extend to the element connecting area portion 3A side of the first substrate 3 and are collectively wired in a first element connecting area 3a. Right-half terminals of a driving element 8 are connected thereto above that portion.

A portion between the first line group 2 and a side edge 3B of the first substrate 3 is provided with a plurality of conductors 9A extending along the side edge 3B. The conductors 9A extend in the vertical direction and arranged in the horizontal direction of FIG. 2. These conductors 9A form a first lead line group 9. The conductors 9A extend to the element connecting area portion 3A side of the first substrate 3 and are collectively wired in a second element connecting area 3b adjacent to the first element connecting area 3a. Left-half terminals of the driving element 8 are connected thereto in this portion.

In FIGS. 2 and 3, the first line group 2 is placed over about two-thirds on the right of the area of the first substrate 3, and the first lead line group 9 is placed over about one-third on the left of the area of the first substrate 3. When the surface pressure distribution sensor 1 according to this embodiment is used as a fingerprint sensor or the like, it is desirable to place the first line group 2 over as large area as possible of the substrate 3 and to place the first lead line group 9 over a small area near the side edge of the substrate 3.

For example, in the application of a fingerprint sensor, a few hundred conductors 2A, e.g., about 200 conductors 2A, each having a width of about 30 to 40 μm, are placed at pitches of about 40 to 50 μm (space between conductors is 10 μm) so as to form the first line group 2. On the other hand, in the first lead line group 9, a few hundred conductors 9A, e.g., about 200 conductors 9A, each having a width of about 10 to 20 μm, e.g., 15 μm, are placed with a space of about 10 μm between the conductors. Accordingly, the first lead line group 9 is placed over an area having a width of one severalth of that of the first line group 2 (in FIG. 2, an area of about half width).

In the plurality of conductors 9A of the first lead line group 9, the lengths thereof are longer near the first line group 2 and shorter in the opposite side of the first line group 2, so that heads of the conductors 9A of the first lead line group 9 are positioned stepwise in the length direction of the first lead line group 9. Also, an insulating layer 10 (see FIGS. 4 and 5) to cover the upper surface of the first substrate 3, the first line group 2, and the first lead line group 9 is provided on the first substrate 3. The insulating layer 10 does not cover the element connecting areas 3a and 3b, so that the connection between the conductors 2A and 9A and the driving element 8 is not blocked. Each of the conductors 2A and 9A is made of an aluminum film or the like having a thickness of about 0.1 μm, and the insulating layer 10 is made of a laminate composed of an insulating material, such as Si3O4 or SiO2.

On the second substrate 6, a plurality of conductors 5A extending in the horizontal direction of FIG. 2 (almost the orthogonal direction with respect to the conductors 2A of the first line group 2) are arranged in parallel in the vertical direction of the second substrate 6, so as to form the second line group 5. The conductors 5A of the second line group 5 have almost the same width as that of the conductors 2A of the first line group 2 and are arranged at almost the same pitches as those of the conductors 2A. The conductors 5A extend to the boundary portion 7 side with constant widths and at constant pitches while serving as conductors 11A of a second lead line group 11, and extend over the boundary portion 7 to the first substrate 3. The conductors 11A connect to the heads of the conductors 9A of the first lead line group 9 on the first substrate 2.

In the above-described configuration, the conductors 5A of the second line group 5 on the second substrate 6 connect to the terminals of the driving element 8 via the conductors 9A of the second lead line group 9 and the conductors 9A of the first lead line group 9 on the first substrate 3. Thus, the conductors 9A of the second lead line group 9 connected to the second line group 5 have the same thickness as that of the conductors 5A of the second line group 5 on the boundary portion 7, extend to the first substrate 3 with the constant thickness, and the width and pitch thereof become small in the conductors 9A of the first lead line group 9. Accordingly, the first lead line group 9 is placed in an area having a width smaller than the width in the arrangement direction of the second line group 5 (the length in the vertical direction in FIG. 2).

Also, an insulating layer 20 to cover the upper surface of the second substrate 6, the second line group 5, and the second lead line group 11 is provided on the second substrate 6. Each of the conductors 5A and 11A is made of an aluminum film or the like having a thickness of about 0.1 μm, and the insulating layer 20 is made of a laminate composed of an insulating material, such as Si3O4 or SiO2.

The second substrate 6 having the above-described configuration is folded on the first substrate 3. In the surface pressure distribution sensor 1 according to this embodiment, a spacer 21 is placed between the first substrate 3 and the second substrate 6 in the overlapped portion of the substrates, along the periphery of the overlapped portion. Accordingly, an air layer 22 corresponding to the thickness of the spacer 21 is formed between the first line group 2 on the first substrate 3 and the second line group 5 on the second substrate 6 facing the first substrate 3. Also, a highly-rigid reinforcing plate 23 made of a stainless steel plate or the like is attached on the rear surface of the second substrate 6. Also, a frame 24 is attached on the outer surface of the second substrate 6 so as to surround the second line group 5 in a plan view. With this configuration, the area inside the frame 24, that is, the area where the plurality of conductors 2A of the first line group 2 and the plurality of conductors 5A of the second line group 5 cross each other at almost 90 degrees in a plan view while facing each other serves as a sensing area S of the surface pressure distribution sensor 1.

The conductors 2A of the first line group 2 and the conductors 5A of the second line group 5 connect to a capacitance detecting circuit 25 and a column selecting circuit 26 included in the driving element 8 as illustrated in FIG. 1, so that the capacitance detecting circuit 25 can detect change in capacitance according to change in clearance in the sensing area S, where the conductors 2A of the first line group 2 and the conductors 5A of the second line group 5 cross each other. In this way, by detecting change in capacitance at many intersections generated when fine concavities and convexities are pressed onto the outer surface of the second substrate 6 made of a flexible film, the shape of the concavities and convexities of an object, e.g., the shape of a fingerprint of a finger 30 illustrated in FIG. 6, can be output as signal data.

The circuit illustrated in FIG. 7 is used as the capacitance detecting circuit 25 used in this embodiment. During measurement, all the conductors 5A of the second line group 5, except the conductors 5A selected by the column selecting circuit 26, are connected to the ground side, and all the capacitance not to be measured on the same conductors 2A of the first line group 2 is input in parallel to a measuring system as parasitic capacitance. However, the electrodes on the opposite side of the parasitic capacitance connect to the ground side, and thus the parasitic capacitance can be canceled. With this configuration, fine concavities and convexities, that is, minute change in capacitance, can be detected with high precision.

In this embodiment, the second line group 5 is placed on the second substrate 6 made of a flexible film. Alternatively, the first line group 2 may be placed on the second substrate 6. However, it is more preferable to place the second line group 5, which connects to the column selecting circuit 26 having low output impedance, on the second substrate 6, in view of a characteristic of being less subject to static electricity.

The application of the surface pressure distribution sensor 1 having the above-described configuration is not limited. For example, the surface pressure distribution sensor 1 can be used as a fingerprint sensor, as illustrated in FIG. 6. By detecting change in capacitance according to change in clearance at the intersections between the conductors 2A of the first line group 2 and the conductors 5A of the second line group 5, the change in capacitance occurring when fine concavities and convexities 27, such as a fingerprint, are pressed onto the surface of the second substrate 6, the shape of the fine concavities and convexities 27, such as the fingerprint of the finger 30, can be precisely detected and can be output as signal data.

When the surface pressure distribution sensor 1 according to this embodiment is applied to a fingerprint sensor, the surface pressure distribution sensor 1 can be applied to a mobile phone owner authentication system, for example. In recent years, settlement has been made by using a mobile phone or the like. By providing the surface pressure distribution sensor 1 in the mobile phone, a fingerprint pressed onto the surface pressure distribution sensor 1 can be precisely detected, and the owner of the phone can be correctly authenticated by comparing the detected fingerprint with fingerprint data registered in advance.

In the surface pressure distribution sensor 1 having the above-described configuration, the conductors 5A of the second line group 5 on the second substrate 6 extend to the first substrate 3 via the boundary portion 7 with the constant thickness, and conductor portions on which folding stress is imposed have a maximum possible thickness. Thus, the conductors 11A placed in the boundary portion 7 as a folded portion are resistant to the folding stress, which contributes to enhancement of the reliability of the lines in the surface pressure distribution sensor 1.

On the other hand, in the surface pressure distribution sensor D having the configuration illustrated in FIGS. 9 and 10, the conductors 116 corresponding to the conductors 9A of the first lead line group 9 of the surface pressure distribution sensor 1 and the conductors 115 corresponding to the conductors 11A of the second lead line group 11 are placed along a side of the sensing area 120 and extend in the same direction, so that the thicknesses of the lead lines 115 and 116 have a direct effect on the width direction of the outer area of the sensing area 120. Therefore, the lead lines 115 and 116 need to be thin and placed at small pitches in order to realize a small size of the substrates of the surface pressure distribution sensor D. The thin lines cause a problem of low durability at the folded portion of the lead lines 116.

On the other hand, in the configuration according to this embodiment, the conductors 11A of the second lead line group 11 are arranged in the direction orthogonal to the plurality of conductors 2A of the first line group 2. Furthermore, the boundary portion 3B having the same vertical width as that of the sensing area S illustrated in FIG. 3 can be used as an area for arranging the conductors 11A, so that the width and the number of the conductors 11A can be the same as those of the conductors 5A. Accordingly, the conductors 11A do not need to be thin and can be placed on the substrates 3 and 6 with the same thickness and at the same pitches as those of the conductors 5A, so that the reliability of the lines can be enhanced.

In view of the arrangement of those conductors, the object of the present invention can be of course achieved by placing the substrate 6 on the right of the substrate 3, instead of placing the substrate 6 on the left of the substrate 3 as illustrated in FIG. 2, such that the arrangement of the lines illustrated in FIG. 2 is formed in a bilaterally-symmetric manner.

### INDUSTRIAL APPLICABILITY

The surface pressure distribution sensor according to the present invention can be used as a fingerprint sensor for a mobile phone owner authentication system, and also can be widely applied to electronic apparatuses, such as an IC card with a fingerprint authentication system, a portable information apparatus, a portable music player, and an electronic key owner authentication system of a car.

### BRIEF DESCRIPTION OF THE DRAWINGS

FIG. 1 is an equivalent circuit diagram of a configuration of a surface pressure distribution sensor according to an embodiment of the present invention.

FIG. 2 illustrates a developed state of first and second substrates of the surface pressure distribution sensor.

FIG. 3 is a plan view illustrating an arrangement of lines of the surface pressure distribution sensor.

FIG. 4 is a cross-sectional view taken along the line A-A′ of the surface pressure distribution sensor illustrated in FIG. 3.

FIG. 5 is a cross-sectional view taken along the line B-B′ of the surface pressure distribution sensor illustrated in FIG. 3.

FIG. 6 is an illustration of a state where the surface pressure distribution sensor detects concavities and convexities.

FIG. 7 is a circuit diagram illustrating an example of a capacitance detecting circuit applied to the surface pressure distribution sensor.

FIG. 8 is an equivalent circuit diagram illustrating an example of a conventional surface pressure distribution sensor.

FIG. 9 is a circuit diagram illustrating a state where another conventional surface pressure distribution sensor is developed.

FIG. 10 illustrates lines of the other conventional surface pressure distribution sensor.

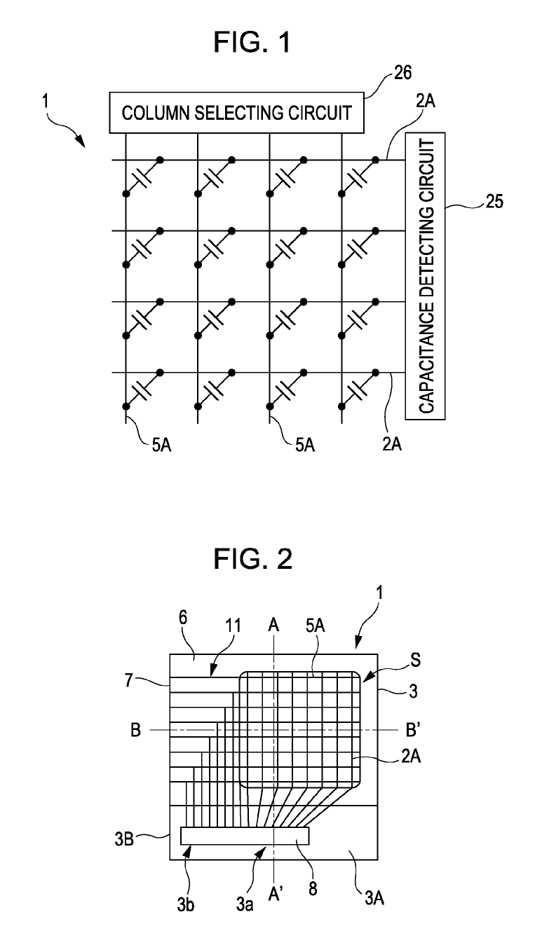

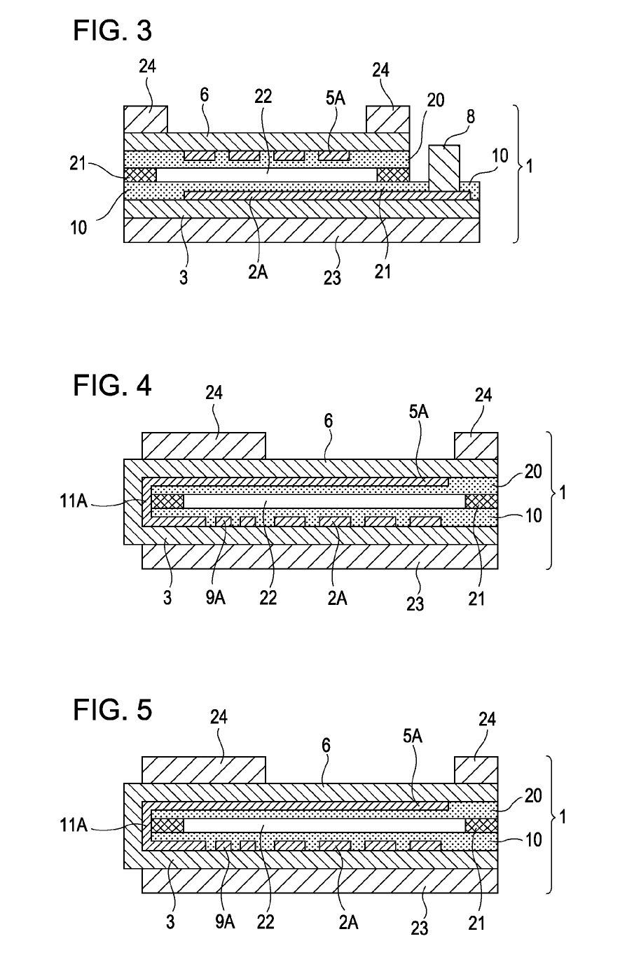

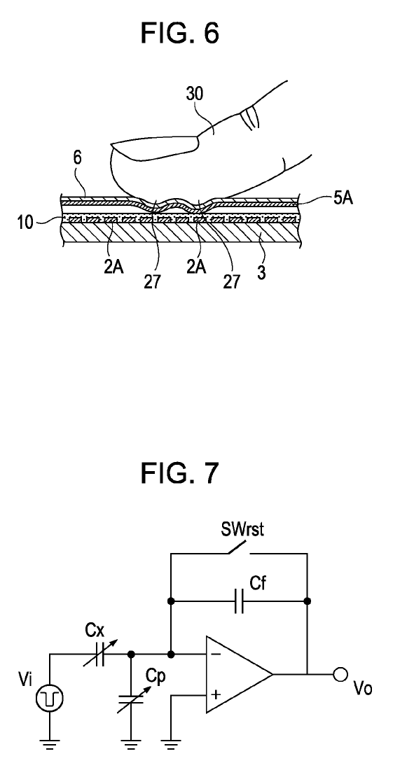

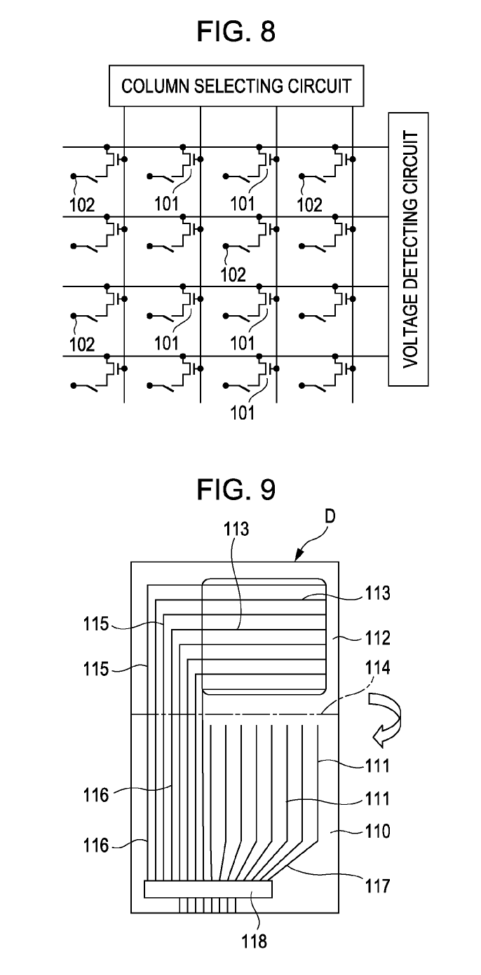

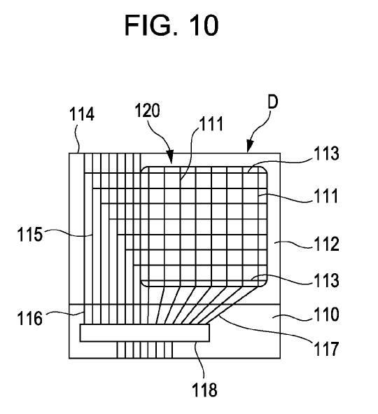

### REFERENCE NUMERALS

1 surface pressure distribution sensor
2 first line group (row lines)
2A conductor
3 first substrate
3a first element connecting area
3b second element connecting area
5 second line group (column lines)
5A conductor
6 second substrate
7 boundary portion
8 driving element
9 first lead line group
9A conductor
10 insulating layer
11 second lead line group
11A conductor

1. A surface pressure distribution sensor that includes a first substrate provided with a first line group having a plurality of conductors arranged in parallel; a second substrate provided with a second line group having a plurality of conductors arranged in parallel; and a boundary portion connecting the first substrate to the second substrate, the first substrate and the second substrate connecting to each other such that folding at the boundary portion allows the first line group of the first substrate and the second line group of the second substrate to face each other and cross each other, and that is capable of detecting distribution of surface pressures based on change in capacitance at intersections of the conductors of the first line group and the conductors of the second line group,
wherein a first lead line group independent of the first line group is placed adjacent to the first line group on the first substrate, a second lead line group connected to the second line group is placed on the second substrate, the second lead line group extends over the boundary portion and connects to the first lead line group on the first substrate, the width of conductors of the first lead line group is smaller than the width of the conductors of the first line group and the width of the conductors of the second line group, and the width of conductors of the second lead line group positioned in a folded portion of the boundary portion is larger than the width of the conductors of the first lead lined group.

2. The surface pressure distribution sensor according to claim 1, wherein the first lead line group is placed in parallel to the first line group on the first substrate, the width of each conductor of the first lead line group is smaller than the width of each conductor of the first line group, the entire width of the first lead lined group is smaller than the entire width of the first line group, the second substrate is connected on a lateral side of the first line group via the boundary portion, and the second line group and the second lead line group are arranged in a direction orthogonal to each conductor of the first lead line group.

3. The surface pressure distribution sensor according to claim 2, wherein one side of the first line group is collectively wired in a part on the first substrate so that a first element connecting area is formed, one side of the first lead line group is collectively wired in another part on the first substrate so that a second element connecting area is formed, the first element connecting area is adjacent to the second element connecting area, and a common sensing driving element or individual sensing driving elements connect to those element connecting areas.

4. The surface pressure distribution sensor according to claim 2, wherein each conductor of the second line group on the second substrate extends over the boundary portion onto the first substrate with a constant width, the conductors of the first lead line group are longer near the first line group and shorter on the opposite side of the first line group so that heads of the conductors of the first lead line group are positioned stepwise in a length direction of the first lead line group, and the conductors of the second lead line group extending over the boundary portion connect to the stepwise-positioned heads of the conductors of the first lead line group.
